(19) United States
(12) Patent Application Publication
(10) Pub. No.: US 2017/0097563 A1
(43) Pub. Date: Apr. 6, 2017

(54) METHODS OF CLEANING SURFACES OF PHOTOMASKS

(71) Applicant: SK hynix Inc., Gyeonggi-do (KR)

(72) Inventor: Goo Min JEONG, Chungcheongbuk-do (KR)

(21) Appl. No.: 15/040,634

(22) Filed: Feb. 10, 2016

(30) Foreign Application Priority Data
Oct. 1, 2015 (KR) 10-2015-0138714

(51) Int. Cl. G03F 1/82

(52) U.S. Cl. CPC G03F 1/82

(57) ABSTRACT

A surface cleaning method includes forming a mask layer on a substrate, performing a first surface treatment process for scanning a surface of the mask layer with a first laser beam to stabilize the mask layer, patterning the mask layer to form a mask pattern, and performing a second surface treatment process for scanning surfaces of the mask pattern and the substrate with a second laser beam to remove contaminants on the mask pattern or the substrate.

### CROSS-REFERENCE TO RELATED APPLICATIONS

The present application claims priority under 35 U.S.C. 119(a) to Korean Patent Application No. 10-2015-0138714, filed on Oct. 1, 2015, which is herein incorporated by reference in its entirety as set forth in full.

### BACKGROUND

1. Technical Field

Various embodiments of the present disclosure relate to lithography technologies and, more particularly, to methods of cleaning surfaces of photomasks.

2. Related Art

As semiconductor devices become more highly integrated, a wavelength of light generated from a light source used in lithography processes has been continuously reduced to improve resolution of patterns transferred onto a wafer. In such a case, defects known as “haze”, which are not generated in a general lithography process using long wavelength light, may be formed on a photomask due to an increase of exposure energy during an exposure step using short wavelength light. If the haze is generated and grown to have a size over a certain value, transmittance of the photomask may be degraded and the exposure energy of the light irradiated onto a wafer may be changed. Accordingly, the haze formed on the photomask may affect the yield of semiconductor devices fabricated on the wafer.

A cleaning process may be used to remove contaminants such as the haze formed on the photomask. Since the cleaning process is applied to surfaces of the photomask, the cleaning process may cause variation of metrology of the photomask. The cleaning process may affect some variations in metrology values such as a light transmittance of the photomask, a light transmittance of mask patterns disposed on a surface of the photomask, critical dimensions (CDs) of the mask patterns, phase angles of the mask patterns, and/or registration of the photomask. That is, the metrology variance of the photomask may lead to non-uniformity of sizes of photoresist patterns formed on a wafer by a photolithography process using the photomask. Accordingly, it may be necessary to suppress or control the metrology variance of the photomask when the cleaning process is performed. The mask patterns may be formed on an effective surface of a mask substrate of the photomask, and the mask patterns formed on the effective surface of the mask substrate may be sealed and protected by a pellicle. Thus, the photomask with the pellicle may be cleaned by the cleaning process.

### SUMMARY

Various embodiments are directed to methods of cleaning surfaces of photomasks. According to an embodiment, there is provided a method of cleaning a surface of a photomask. The method includes forming a mask layer on a substrate, performing a first surface treatment process for scanning a surface of the mask layer with a first laser beam to stabilize the mask layer, patterning the mask layer to form a mask pattern, and performing a second surface treatment process for scanning surfaces of the mask pattern and the substrate with a second laser beam to remove contaminants on the mask pattern or the substrate.

According to another embodiment, there is provided a method of cleaning a surface of a photomask. The method includes forming a first mask layer on a substrate, forming a second mask layer on the first mask layer to realize a mask layer including the first and second mask layers, and performing a first surface treatment process for scanning a surface of the substrate, the first mask layer or the second mask layer with a first laser beam to stabilize the substrate or the mask layer. The mask layer is patterned to form a mask pattern. A second surface treatment process for scanning surfaces of the mask pattern and the substrate with a second laser beam is performed to remove contaminant on the mask pattern or the substrate.

### BRIEF DESCRIPTION OF THE DRAWINGS

Various embodiments of the present disclosure will become more apparent in view of the attached drawings and accompanying detailed description, in which:

FIG. 1 is a process flowchart illustrating a method of cleaning a surface of a photomask according to an embodiment;

FIG. 2 is a schematic view illustrating a surface treatment system performing a cleaning process shown in FIG. 1;

FIGS. 3 to 10 are cross-sectional views illustrating a method of cleaning a surface of a photomask according to an embodiment;

FIG. 11 is a graph illustrating a CD variation of mask patterns depending on a number of photomask scans with a laser beam according to an embodiment;

FIG. 12 is a graph illustrating a variation in light transmittance of mask patterns depending on the number of photomask scans with a laser beam according to an embodiment;

FIG. 13 is a graph illustrating a phase angle variation in mask patterns depending on the number of photomask scans with a laser beam according to an embodiment;

FIG. 14 illustrates a registration variation in a photomask depending on the number of photomask scans with a laser beam according to an embodiment; and

FIG. 15 is a process flowchart illustrating a method of cleaning a surface of a photomask according to another embodiment.

### DETAILED DESCRIPTION OF THE EMBODIMENTS

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms including technical and scientific terms used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concept.

It will also be understood that when an element or layer is referred to as being “on,” “over,” “below,” “under,” or “outside” another element or layer, the element or layer may be in direct contact with the other element or layer, or intervening elements or layers may be present. Other words used to describe the relationship between elements or layers should be interpreted in a like fashion for example, “between” versus “directly between” or “adjacent” versus “directly adjacent”.

The terminology “pattern” used herein may indicate a mask pattern such as a light blocking pattern or a phase shift pattern that is formed on a photomask to realize an element of an electronic circuit or an integrated circuit of a semiconductor device. The semiconductor device may correspond to a memory device or a logic device. The memory device may be a dynamic random access memory (DRAM) device, a static random access memory (SRAM) device, a flash memory device, a magnetic random access memory (MRAM) device, a resistive random access memory (ReRAM) device, a ferroelectric random access memory (FeRAM) device, or a phase change random access memory (PcRAM) device. The semiconductor device may be employed in communication systems such as mobile phones, electronic systems associated with biotechnology or health care, or wearable electronic systems.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing.

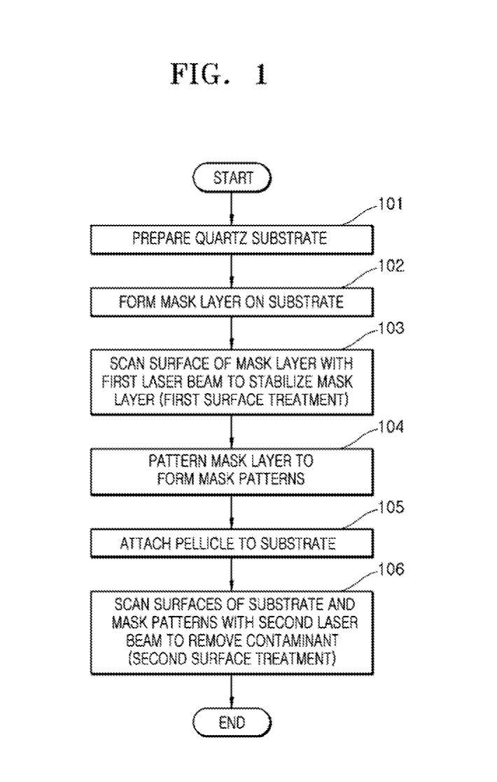

FIG. 1 is a process flowchart illustrating a method of cleaning a surface of a photomask according to an embodiment. Referring to FIG. 1, the cleaning method of a photomask according to an embodiment may be performed to remove defects or contaminant such as haze that to can be formed on a surface of the photomask.

Specifically, the cleaning method according to an embodiment may include preparing a light transmitting substrate such as a quartz substrate (see a step 101), forming a mask layer on the substrate (see a step 102), performing a first surface treatment process for scanning a surface of the mask layer with a first laser beam to stabilize the mask layer (see a step 103), patterning the mask layer to form mask patterns (see a step 104), attaching a pellicle to the substrate (see a step of 105), and performing a second surface treatment process for scanning surfaces of the mask patterns and the substrate with a second laser beam to remove contaminants (see a step 106). A substantial effect of the cleaning method may be obtained during the second surface treatment process (106).

The second surface treatment process (106) utilizing the second laser beam may supply thermal energy to decompose the contaminant formed on the photomask. That is, the contaminant formed on the photomask may be heated and decomposed by pulses of the second laser beam during the second surface treatment process. For example, during the second surface treatment process, the substrate and the mask patterns of the photomask may be heated up to a temperature over 280 degrees Celsius to decompose a haze such as ammonium sulphate.

A laser beam with a continuous wavelength may be used as the second laser beam. However, any laser beam having an appropriate wavelength to be absorbed into the substrate and the mask patterns of the photomask can be used as the second laser beam. The second laser beam may have a wavelength which is within the range corresponding to a local maximum peak value of an absorption spectrum of the substrate or the mask patterns.

While a wavelength bandwidth of the laser beam absorbed into a metal material of the mask patterns is relatively broad, a wavelength bandwidth of the laser beam absorbed into the quartz substrate may be relatively narrow. Accordingly, the second laser beam may be limited to a laser beam that can be absorbed into the quartz substrate. In some embodiments, the second laser beam may be a laser beam having a wavelength longer than 8 micrometers, for example, a wavelength of about 9 micrometers.

During the second surface treatment process (106), the photomask may be heated up by the second laser beam to a predetermined temperature so that the substrate and the mask patterns are not damaged while the haze is decomposed. For example, the photomask may be heated up to a temperature of about 280 degrees Celsius to about 350 degrees Celsius during the second surface treatment process (106).

The first surface treatment process (103) may be performed to suppress or prevent the metrology of the photomask from varying during the second surface treatment process (106). The quality of the photomask may be controlled by measuring various characteristics related to the metrology of the photomask and by monitoring variations of the various characteristics related to the metrology of the photomask. For example, the quality of the photomask may be controlled and evaluated by measuring light transmittance of the photomask, light transmittance of the mask patterns formed on the photomask, critical dimensions (CDs) of the mask patterns, phase angles of the mask patterns, registration of the photomask and by monitoring variations of the measured characteristics of the photomask.

Since the thermal energy is applied to the photomask during the second surface treatment process (106), it may be important to prevent or minimize variations of the various characteristics of the photomask during the second surface treatment process (106). The first surface treatment process (103) may be applied to a blank mask including the quartz substrate and the mask layer formed on an entire surface of the quartz substrate. That is, the first surface treatment process (103) may be performed to supply thermal energy to the mask layer and the substrate in advance before the mask layer is patterned. Thus, the mask layer and the substrate may be thermally stabilized by the first surface treatment process (103). Accordingly, even though additional thermal energy is supplied to the substrate and the mask patterns during the second surface treatment process (106), variations of the various characteristics of the substrate and the mask patterns may be suppressed or minimized while the second surface treatment process (106) is performed.

The second surface treatment process (106) may be performed under substantially the same condition as the first surface treatment process (103). For example, a wavelength of the second laser beam may be substantially equal to that of the first laser beam. In addition, the scanning of the first laser beam may induce a temperature increase substantially as same as the temperature increase due to the scanning of the second laser beam in the substrate and the mask layer.

The metrology variations of the substrate, the mask layer and the mask patterns may be due to a thermal energy. Thus, in some embodiments, the first laser beam used in the first surface treatment process (103) may have a wavelength which is different from a wavelength of the second laser beam used in the second surface treatment process (106), and a temperature variation of the substrate and the mask layer scanned by the first laser beam may be greater than a temperature variation of the substrate and the mask patterns scanned by the second laser beam.

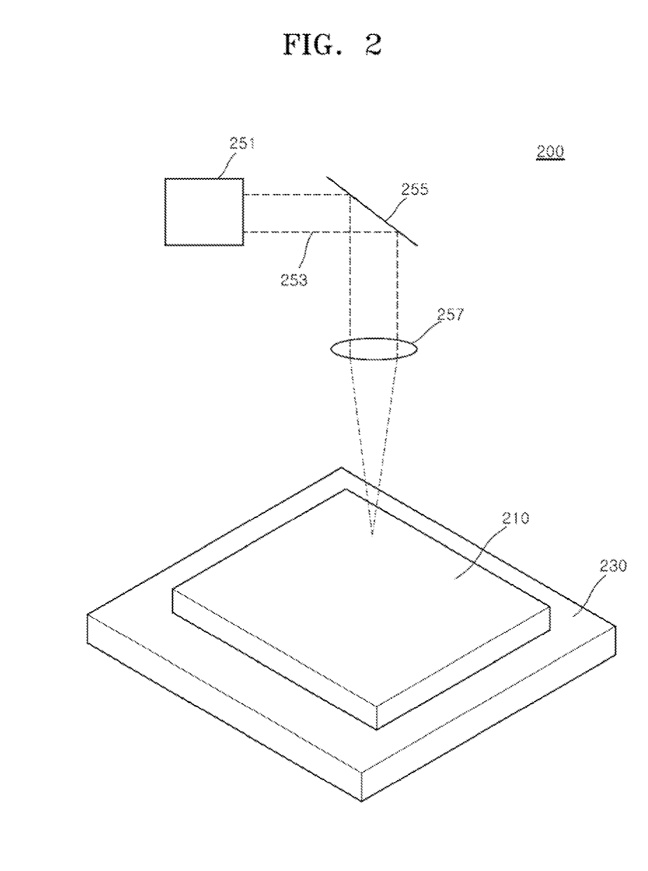

FIG. 2 is a schematic view illustrating a surface treatment system 200 performing the cleaning process shown in FIG. 1. Referring to FIG. 2, the surface treatment system 200 may be used to perform the second surface treatment process (106 of FIG. 1) for cleaning the surface of the photomask. The surface treatment system 200 may also be used to perform the first surface treatment process (103 of FIG. 1) corresponding to a pre-treatment process for stabilizing the mask layer.

The surface treatment system 200 may include a chuck 230 on which a photomask 210 is loaded. In some embodiments, the chuck 230 may be three-dimensionally movable. The surface treatment system 200 may further include a laser source 251 generating a pulsed laser beam 253. The laser source 251 may generate optical pulses.

Although FIG. 2 illustrates an example in which the surface treatment system 200 includes a single laser source 251, the present disclosure is not limited thereto. For example, in some embodiments, the surface treatment system 200 may include a plurality of laser sources generating laser beams that have the same wavelength or different wavelengths. A steering mirror 255 and a focus objective lens 257 may be disposed between the laser source 251 and the chuck 230 (i.e., the photomask 210). The steering mirror 255 may change a direction of the pulsed laser beam 253 emitted from the laser source 251 such that the pulsed laser beam 253 travels toward the focus objective lens 257. The focus objective lens 257 may focus the pulsed laser beam 253 on the photomask 210.

In some embodiments, the focus objective lens 257 may be three-dimensionally movable. The first surface treatment process (103 of FIG. 1) or the second surface treatment process (106 of FIG. 1) may be performed using the surface treatment system 200 such that the first laser beam or the second laser beam corresponding to the pulsed laser beam 253 is irradiated onto the photomask 210. As the pulsed laser beam 253 corresponding to the first or second laser beam is irradiated onto the photomask 210, the substrate and the mask layer may be thermally stabilized or the haze on the photomask 210 may be removed.

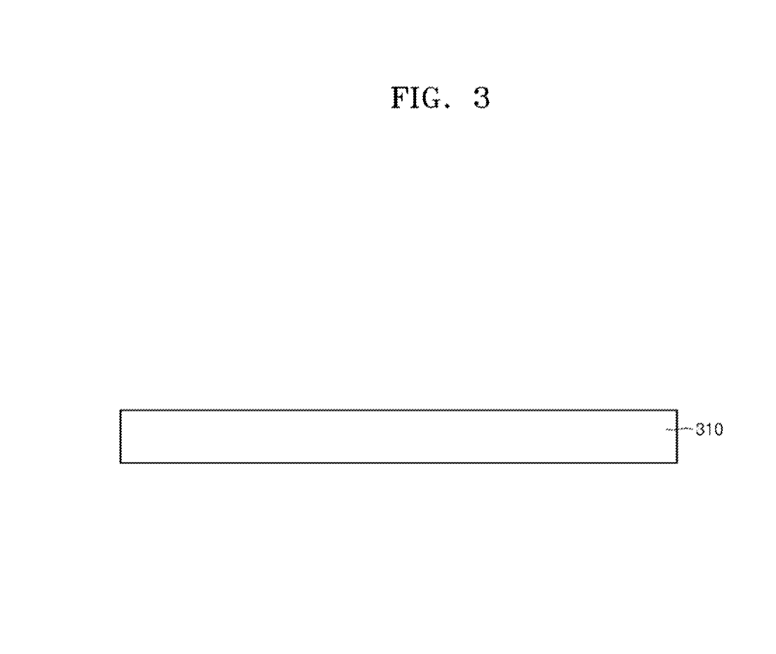

FIGS. 3 to 10 are cross-sectional views illustrating a method of cleaning a surface of a photomask according to an embodiment. Referring to FIG. 3, a transparent substrate 310 such as a light transmitting substrate may be provided. The substrate 310 may be a quartz substrate. More specifically, the substrate 310 may be a quartz substrate having a relatively low absorption coefficient of a deep ultraviolet (DUV) ray. The first surface treatment process (103 of FIG. 1) may be applied to the substrate 310 to stabilize a surface of the substrate 310.

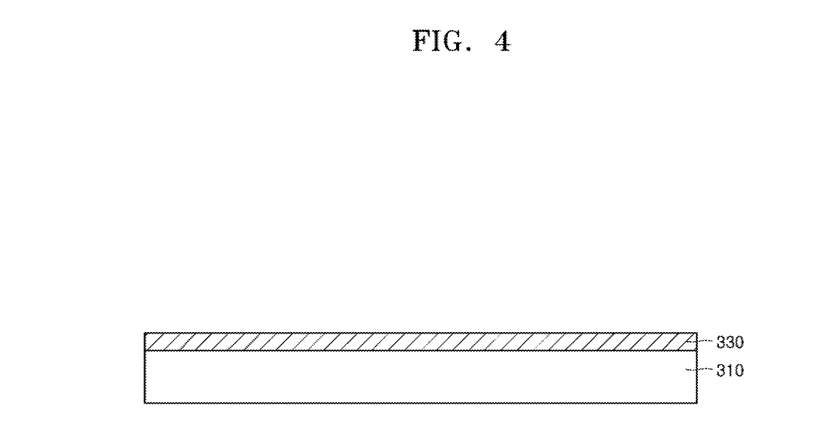

Referring to FIG. 4, a first mask layer 330 may be formed on the stabilized surface of the substrate 310. The first mask layer 330 may be a phase shift layer, for example, a molybdenum silicon (MoSi) alloy layer. The first mask layer 330 may be deposited on an entire surface of the substrate 310. After the first mask layer 330 is formed, the first surface treatment process (103 of FIG. 1) may be applied to the first mask layer 330 to stabilize the first mask layer 330.

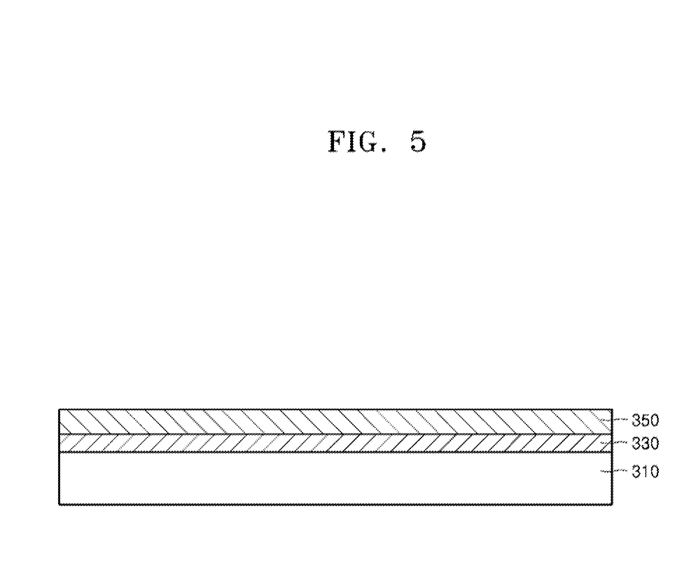

Referring to FIG. 5, a second mask layer 350 may be formed on the first mask layer 330. The second mask layer 350 may include a chrome (Cr) layer serving as a light blocking layer. The second mask layer 350 may be formed on an entire surface of the first mask layer 330. The first and second mask layers 330 and 350 may constitute a mask layer, and the mask layer may be patterned to form mask patterns in a subsequent process.

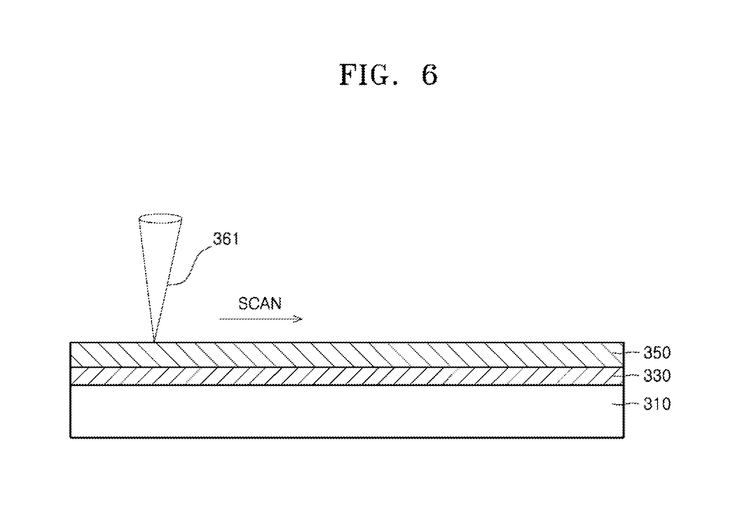

Referring to FIG. 6, the first surface treatment process (103 of FIG. 1) may be applied to the second mask layer 350 to stabilize the mask layer 330+350 and the substrate 310. The first surface treatment process (103 of FIG. 1) may be performed using the surface treatment system (200 of FIG. 2). Specifically, a surface of the second mask layer 350 may be scanned by a first laser beam 361 to increase a temperature of the mask layer 330+350 and the substrate 310. In such a case, metrological characteristics of the substrate 310 and the mask layer 330+350 may vary to thermally stabilize the substrate 310 and the mask layer 330+350. The first laser beam 361 may create a beam spot, and an entire surface of the second mask layer 350 may be scanned with the first laser beam 361 by two-dimensionally moving the spot of the first laser beam 361 or by two-dimensionally moving the substrate 310. Thus, the metrological characteristics of the substrate 310 and the mask layer 330+350 may not vary any more during the second surface treatment process (106 of FIG. 1) to be performed afterwards.

The first surface treatment process (103 of FIG. 1) applied to the surface of the substrate 310 before formation of the first mask layer 330 may correspond to a first sub-step of the first surface treatment process, the first surface treatment process (103 of FIG. 1) applied to the surface of the first mask layer 330 before formation of the second mask layer 350 may correspond to a second sub-step of the first surface treatment process, and the first surface treatment process (103 of FIG. 1) applied to the surface of the second mask layer 350 may correspond to a third sub-step of the first surface treatment process. In some embodiments, one or both of the first and second sub-steps of the first surface treatment process may be omitted.

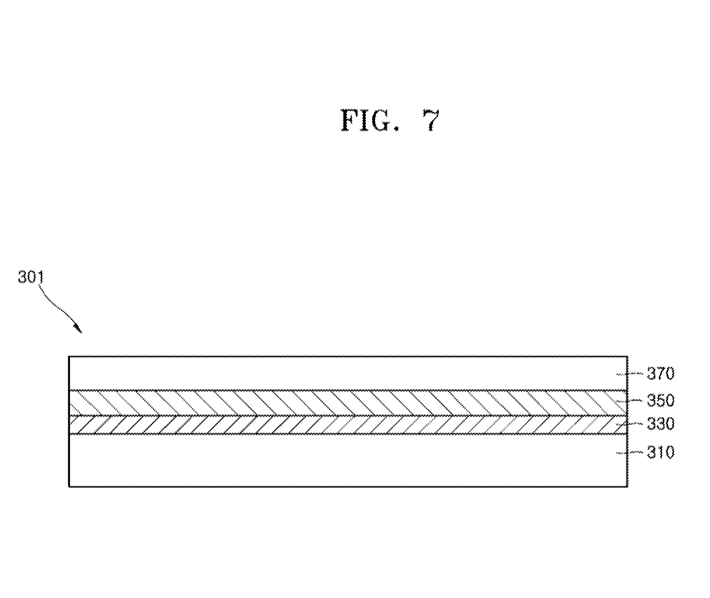

Referring to FIG. 7, a photoresist layer 370 may be formed on the second mask layer 350 after the third sub-step of the first surface treatment process is performed. The substrate 310, the first mask layer 330, the second mask layer 350 and the photoresist layer 370 may constitute a blank mask 301. Although not shown in the drawings, the photoresist layer 370 may be patterned by a photolithography process to form photoresist patterns. The photoresist patterns may be used as etch masks when the mask layer 330+350 is patterned in a subsequent process.

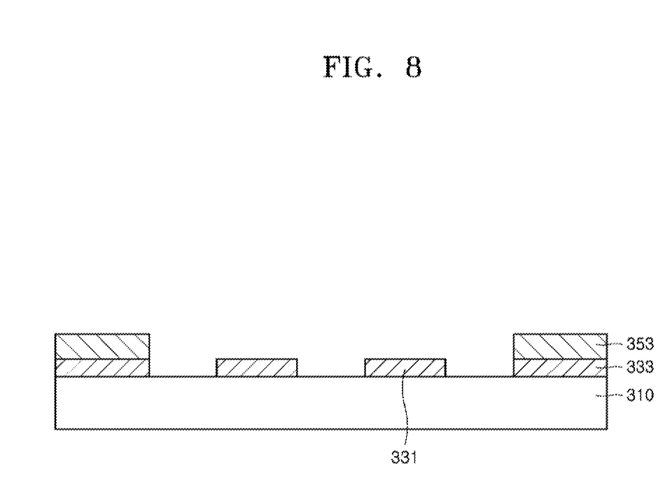

Referring to FIG. 8, the mask layer (330+350 of FIG. 7) may be patterned to form mask patterns including first mask patterns 331 and 333 and a second mask pattern 353 which are located on the substrate 310. The first mask patterns 331 and 333 may be formed to include a first frame mask pattern 333 disposed in an outer frame region of the substrate 310 and first inner mask patterns 331 disposed in an inner region of the substrate 310. Images of the first inner mask patterns 331 may be transferred onto a wafer during an exposure step. The second mask pattern 353 may be stacked on the first frame mask pattern 333 to serve as a second frame mask pattern. The first and second mask patterns 331, 333 and 353 may be formed to realize a phase shift mask.

Although the present embodiment illustrates a phase shift mask, the present disclosure is not limited to a method of cleaning the phase shift mask. For example, the present disclosure is applicable to a method of cleaning a binary mask.

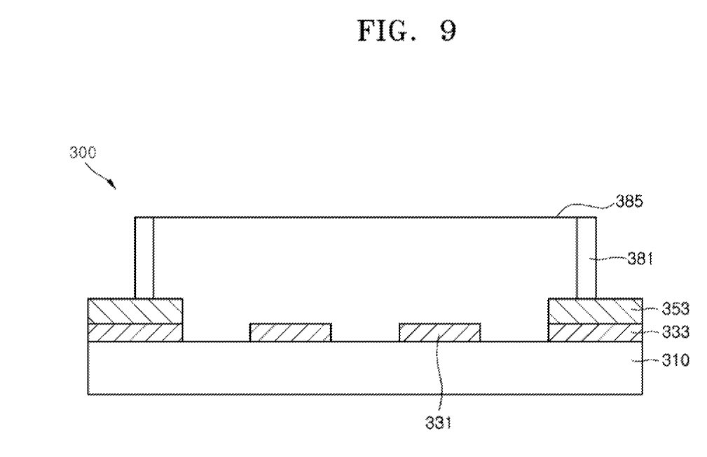

Referring to FIG. 9, after the mask patterns 331, 333 and 353 are formed, a frame 381 may be attached to the second mask pattern 353 such that a pellicle 385 is located over the first inner mask patterns 331. That is, the frame 381 to which the pellicle 385 is attached may be placed on the substrate 310. The frame 381 may be attached to the second mask pattern 353. The pellicle 385 may be attached to the second mask pattern 353 by the frame 381 to serve as a protection layer that protects the first inner mask patterns 331 whose images are transferred onto a wafer.

The pellicle 385 may seal a space on the first inner mask patterns 331 surrounded by the first and second mask patterns 333 and 353. As a result, the space on the first inner mask patterns 331 may be isolated from an external environment by the pellicle 385. After the pellicle 385 is attached to the second mask pattern 353 using the frame 381, a photomask 300 may be completely fabricated. If the photomask 300 is used in an exposure step, images of the first inner mask patterns 331 protected by the pellicle 385 may be transferred onto a wafer.

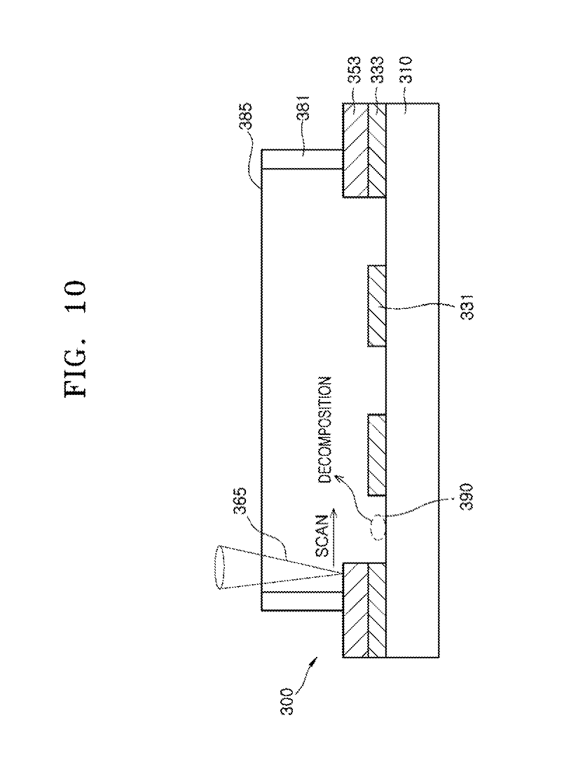

Referring to FIG. 10, the photomask 300 may be used in an exposure step of a photolithography process, and contaminant 390 such as haze may be formed on a surface of the substrate 310 or the mask patterns of the photomask 300 due to high exposure energy while the exposure step is performed. Thus, the second surface treatment process (106 of FIG. 1) may be performed to remove the contaminant 390 without detaching the pellicle 385 from the substrate 310.

The second surface treatment process (106 of FIG. 1) may be performed using the surface treatment system (200 of FIG. 2). Specifically, the photomask 300 may be scanned using a second laser beam 365 to decompose the contaminant 390. While the photomask 300 is scanned using the second laser beam 365, the second laser beam 365 may penetrate the pellicle 385 to reach a surface of the substrate 310, a surface of the first inner mask patterns 331, and a surface of the second mask pattern 353.

The photomask 300 may be repeatedly scanned using the second laser beam 365 two or more times to increase a temperature of the substrate 310 and the mask patterns 331 and 353. If the temperature of the substrate 310 and the mask patterns 331 and 353 increases, a temperature of the contaminant 390 formed on the surface of the substrate 310 or the mask patterns 331 and 353 may also increase. That is, while the second surface treatment process (106 of FIG. 1) is performed, thermal energy generated by the second laser beam 365 may be transmitted to the contaminant 390 and the contaminant 390 may be heated up. If the contaminant 390 is heated up to a predetermined temperature, for example, a temperature over 280 degrees Celsius, the contaminant 390 may be decomposed and may be removed from the surface of the photomask 300.

If no surface treatment process such as, the first to third sub-steps of the first surface treatment process, is performed before the second surface treatment process (106 of FIG. 1), the substrate 310 or the mask patterns 331 and 353 may be deformed due to thermal energy generated during the second surface treatment process (106 of FIG. 1). This thermal deformation of the substrate 310 or the mask patterns 331 and 353 may cause variation of metrological characteristics such as sizes and physical characteristics of the substrate 310 or the mask patterns 331 and 353.

For example, in the event that no first surface treatment process such as, the first to third sub-steps of the first surface treatment process, is performed before the second surface treatment process (106 of FIG. 1), the second surface treatment process (106 of FIG. 1) may cause variation of the light transmittance of the substrate 310, variation of the light transmittance of the first inner mask patterns 331, variation in pattern size of the first inner mask patterns 331, variation of the phase angles of the first inner mask patterns 331, and/or variation of the registration characteristic of the photomask 300. However, according to the embodiment, at least one of the first to third sub-steps of the first surface treatment process may be performed before the second surface treatment process (106 of FIG. 1) to improve the thermal resistivity of the substrate 310 and the mask patterns 331 and 353. Thus, even though the second surface treatment process (106 of FIG. 1) is performed to remove the contaminant 390, the thermal deformation of the photomask 300 may be suppressed or prevented.

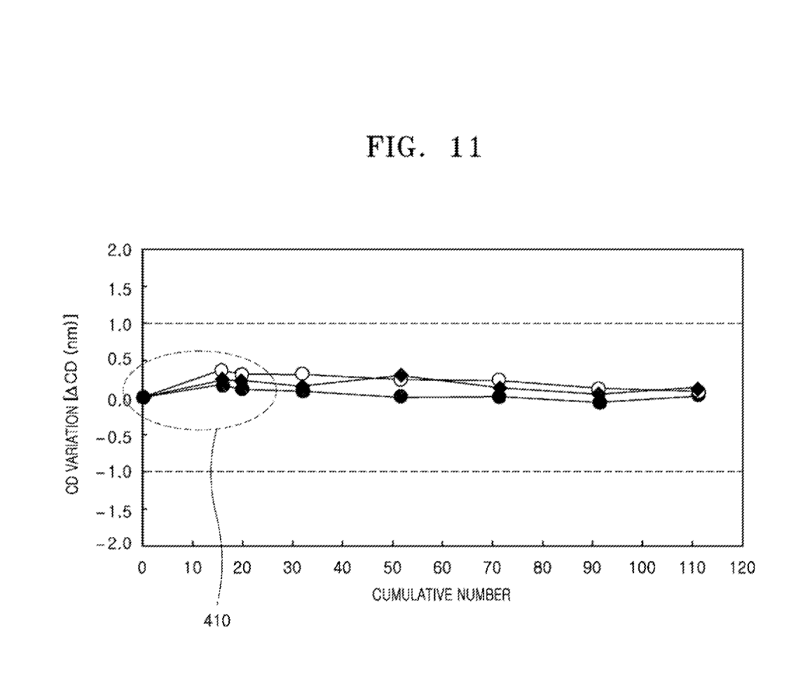

FIG. 11 is a graph illustrating a variation in pattern size of mask patterns with respect to the number of scans. Three photomasks 300, shown in FIGS. 9 and 10, were scanned with a second laser beam in a method of cleaning the photomasks 300 according to an embodiment. In the graph of FIG. 11, the abscissa denotes the cumulative number of repeatedly scanning each photomask 300 with the second laser beam used in the second surface treatment process (106 of FIG. 1), and the ordinate denotes a variation in pattern size of the first inner mask patterns (331 of FIG. 10). FIG. 11 is a graph illustrating data obtained when the first surface treatment process (103 of FIG. 1) is omitted.

Referring to FIG. 11, when the second surface treatment process (106 of FIG. 1) is performed without the first surface treatment process (103 of FIG. 1), the variation in pattern size of the first inner mask patterns 331 reduces as the cumulative number of repeated scans of the photomask 300 with the second laser beam increases. More specifically, the variation in pattern size of the first inner mask patterns 331 continuously increases from a value of zero in a region 410 that the photomask 300 is repeatedly scanned, to about sixteen times to about twenty times. However, the variation in pattern size of the first inner mask patterns 331 decreases when the cumulative number of repeated scans of the photomask 300 with the second laser beam is greater than twenty. Thus, it can be understood that the thermal deformation of the substrate 310 and/or the first inner mask patterns 331 occurs severely during an Initial scanning step, i.e., until the cumulative number of repeated scans of the photomask 300 with the second laser beam reaches about sixteen to twenty.

The first surface treatment process (103 of FIG. 1) may be performed to intentionally cause metrology variation of the substrate 310 and/or the mask layer 330+350. The first surface treatment process causes thermal deformation of the substrate 310 and/or the first inner mask patterns 331 during the second surface treatment process (106 of FIG. 1)) in advance before the second surface treatment process (106 of FIG. 1). The first surface treatment process (103 of FIG. 1) may be performed under the same process condition as the second surface treatment process (106 of FIG. 1). For example, the first surface treatment process (103 of FIG. 1) may be performed using the same laser beam that is, the first laser beam, as the second laser beam used in the second surface treatment process (106 of FIG. 1) and the same apparatus as the surface treatment system (200 of FIG. 2) used in the second surface treatment process (106 of FIG. 1).

In such a case, during the first surface treatment process (103 of FIG. 1), the substrate 310 or the mask layer 330+350 may be repeatedly scanned using the first laser beam at least twenty times. Accordingly, the thermal deformation of the substrate 310 and the first inner mask patterns 331 may be prevented or suppressed during the second surface treatment process (106 of FIG. 1) when the first surface treatment process (103 of FIG. 1) is performed before the second surface treatment process (106 of FIG. 1).

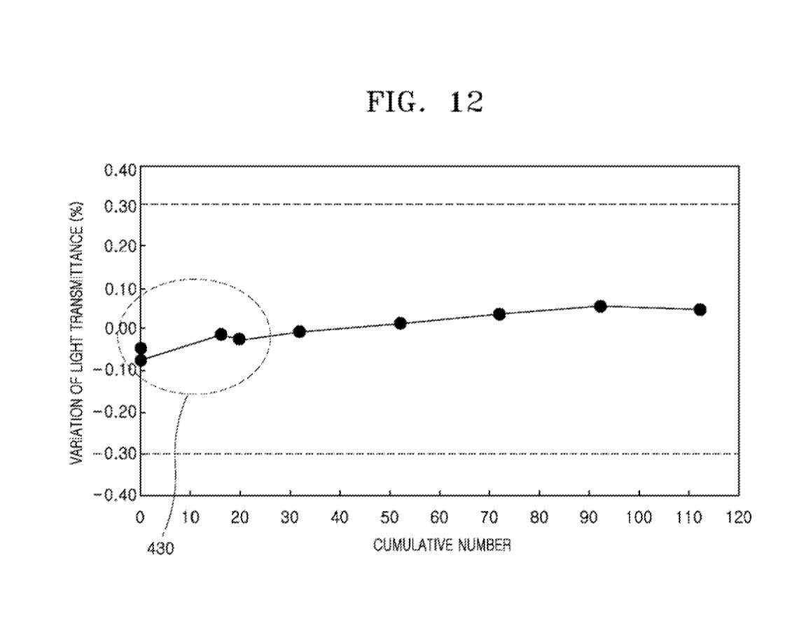

FIG. 12 is a graph illustrating variation of a light transmittance of the mask patterns (331 of FIG. 10) with respect to the number of scans of the photomask 300 with a laser beam in a method of cleaning the photomask 300 according to an embodiment. In the graph of FIG. 12, the abscissa denotes the cumulative number of repeated scans of the photomask 300 with the second laser beam used in the second surface treatment process (106 of FIG. 1), and the ordinate denotes variation of light transmittance of the first inner mask patterns (331 of FIG. 10). FIG. 12 corresponds to a graph illustrating data obtained when the first surface treatment process (103 of FIG. 1) is omitted.

Referring to FIG. 12, when the second surface treatment process (106 of FIG. 1) is performed without the first surface treatment process (103 of FIG. 1), variation of light transmittance of the first inner mask patterns 331 continuously increases from a negative value toward a value of zero in a region 430 until the photomask 300 is repeatedly scanned about sixteen times to about twenty times. The variation of the light transmittance of the first inner mask patterns 331 reached approximately zero when the cumulative number of repeated scans of the photomask 300 with the second laser beam is more than twenty.

Furthermore, the thermal deformation of the substrate 310 and/or the first inner mask patterns 331 occurs severely during an initial scanning step, i.e., until the cumulative number of repeated scans of the photomask 300 with the second laser beam reaches about sixteen to twenty. Thus, the first surface treatment process (103 of FIG. 1) may be performed in advance before the second surface treatment process (106 of FIG. 1) to intentionally cause metrology variation of the substrate 310 and/or the mask layer 330+350 corresponding to the thermal deformation of the substrate 310 and/or the first inner mask patterns 331 occurring during the second surface treatment process (106 of FIG. 1). In such a case, the thermal deformation of the substrate 310 and the first inner mask patterns 331 may be prevented or suppressed during the second surface treatment process (106 of FIG. 1).

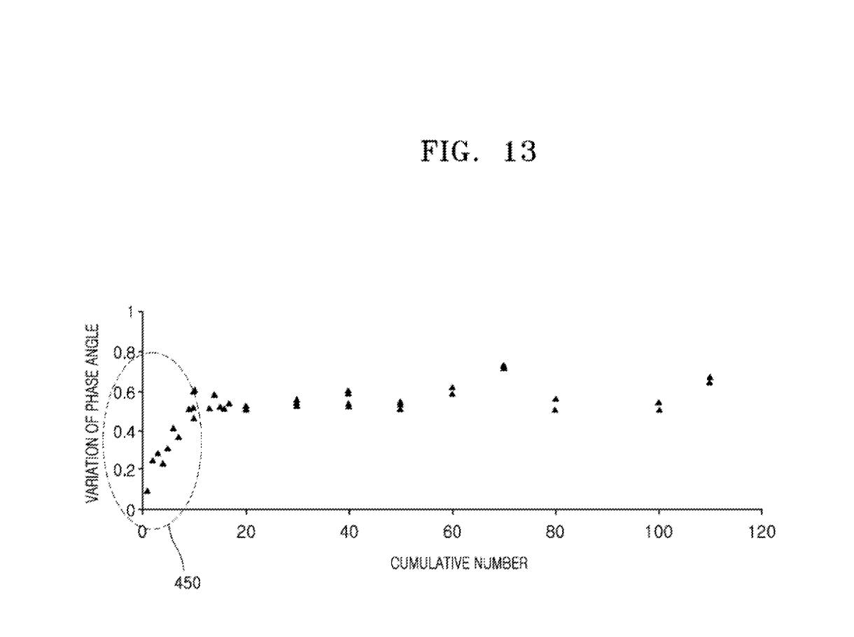

FIG. 13 is a graph Illustrating a phase angle variation of mask patterns (331 of FIG. 10) with respect to the number of scans of a photomask 300 with a laser beam in a method of cleaning the photomask 300 according to an embodiment. In the graph of FIG. 13, the abscissa denotes the cumulative number of repeated scans of the photomask 300 with the second laser beam used in the second surface treatment process (106 of FIG. 1), and the ordinate denotes variation of a phase angle of the first inner mask patterns (331 of FIG. 10). FIG. 13 corresponds to a graph Illustrating data obtained when the first surface treatment process (103 of FIG. 1) is omitted.

Referring to FIG. 13, when the second surface treatment process (106 of FIG. 1) is performed without the first surface treatment process (103 of FIG. 1), variation of the phase angle of the first inner mask patterns 331 continuously increases in a region 450 until the photomask 300 is repeatedly scanned about sixteen times to about twenty times. The variation of the light transmittance of the first inner mask patterns 331 reaches a specific value when the cumulative number of repeated scans of the photomask 300 with the second laser beam is more than twenty.

Furthermore, the thermal deformation of the substrate 310 and/or the first inner mask patterns 331 occurs severely during an initial scanning step, that is, until the cumulative number of repeated scans of the photomask 300 with the second laser beam reaches about sixteen to twenty. Thus, the first surface treatment process (103 of FIG. 1) may be performed in advance before the second surface treatment process (106 of FIG. 1) to intentionally cause metrology variation of the substrate 310 and/or the mask layer 330+350 corresponding to the thermal deformation of the substrate 310 and/or the first inner mask patterns 331 occurring during the second surface treatment process (106 of FIG. 1). In such a case, the thermal deformation of the substrate 310 and the first Inner mask patterns 331 may be prevented or suppressed during the second surface treatment process (106 of FIG. 1).

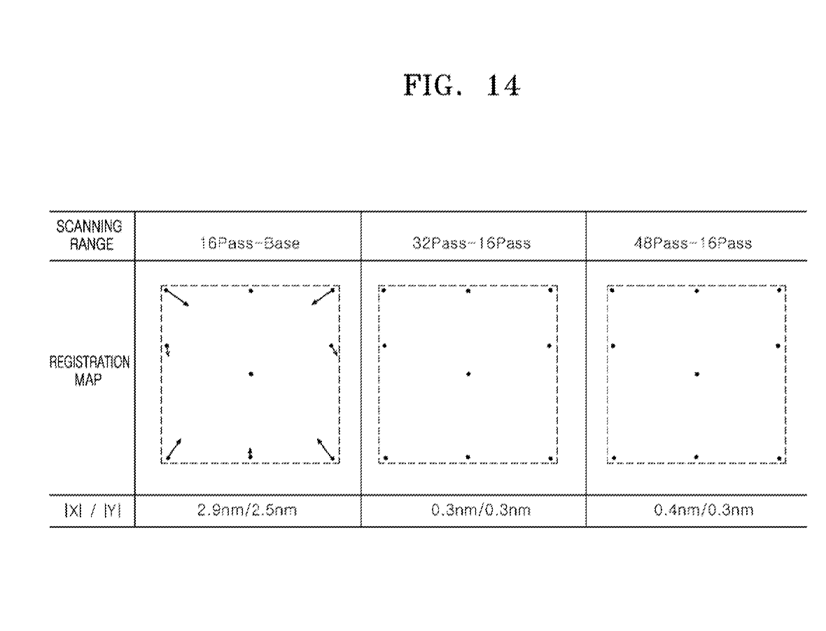

FIG. 14 illustrates a registration variation of a photomask 300 with respect to the number of scans of the photomask 300 with a laser beam in a method of cleaning the photomask 300 according to an embodiment. FIG. 14 illustrates data obtained when the first surface treatment process (103 of FIG. 1) is omitted.

Referring to FIG. 14, when the second surface treatment process (106 of FIG. 1) is performed without the first surface treatment process (103 of FIG. 1), disposition error rates that is, registration error rates of the first inner mask patterns 331 remarkably increase until the photomask 300 is repeatedly scanned about sixteen times. The disposition error rates of the first inner mask patterns 331 reaches approximately zero when the cumulative number of repeated scans of the photomask 300 with the second laser beam is more than sixteen.

Considering registration maps illustrated in FIG. 14, the registration error of the first inner mask patterns 331 in an X-axis direction was 2.9 nanometers and the registration error of the first inner mask patterns 331 in a Y-axis direction was 2.5 nanometers after the photomask 300 was repeatedly scanned by the second laser beam about sixteen times. However, when the cumulative number of repeated scans of the photomask 300 with the second laser beam was thirty two, the additional registration error of the first inner mask patterns 331 in the X-axis direction was 0.3 nanometers and the registration error of the first inner mask patterns 331 in the Y-axis direction was 0.3 nanometers. Furthermore, when the cumulative number of repeated scans of the photomask 300 with the second laser beam was forty eighth, the registration error of the first inner mask patterns 331 in the X-axis direction was 0.4 nanometers and the registration error of the first inner mask patterns 331 in the Y-axis direction was 0.3 nanometers.

Furthermore, thermal deformation of the first inner mask patterns 331 and/or the substrate 310 rarely occurs in a region that the cumulative number of repeated scans of the photomask 300 with the second laser beam is more than sixteen. That is, the thermal deformation of the substrate 310 and/or the first inner mask patterns 331 occurs severely during an initial scanning step that is, until the cumulative number of the second surface treatment process (106 of FIG. 1) reaches sixteen.

Thus, the first surface treatment process (103 of FIG. 1) may be performed in advance before the second surface treatment process (106 of FIG. 1) to intentionally cause metrology variation of the substrate 310 and/or the mask layer 330+350 corresponding to the thermal deformation of the substrate 310 and/or the first inner mask patterns 331 occurring during the second surface treatment process (106 of FIG. 1). In such a case, the thermal deformation of the substrate 310 and the first inner mask patterns 331 may be prevented or suppressed during the second surface treatment process (106 of FIG. 1).

The second surface treatment process for obtaining the data shown in FIGS. 11 to 14 was performed using a Rhazer® haze removal system provided by the RAVE Company. In consideration of the data shown in FIGS. 11 to 14, the cumulative number of repeated scans of at least one of the substrate 310, the first mask layer 330 and the second mask layer 350 with the first laser beam used in the first surface treatment process may be set to at least twenty. In addition, the first and second surface treatment processes 103 and 106 may be performed using the same laser beam and the same surface treatment system. That is, the first laser beam used in the first surface treatment process 103 may have the same wavelength as the second laser beam used in the second surface treatment process 106, and the first and second surface treatment processes 103 and 106 may be performed using the same apparatus.

Moreover, as described with reference to FIGS. 11 to 14, metrology variations of the substrate 310 and the mask patterns 331 of the photomask 300 may be obtained by measuring the size or properties of the photomask 300 whenever the photomask 300 is scanned by the second laser beam used in the second surface treatment process 106. The minimum scanning number of the first laser beam used in the first surface treatment process 103 may be extracted from the metrology variations of the substrate 310 and the mask patterns 331. When at least one of the substrate 310, the first mask layer 330 and the second mask layer 350 is repeatedly scanned with the first laser beam used in the first surface treatment process 103 at least the minimum scanning number, the thermal deformation of the substrate 310 and/or the mask patterns 331 may be suppressed or prevented while the second surface treatment process 106 is performed.

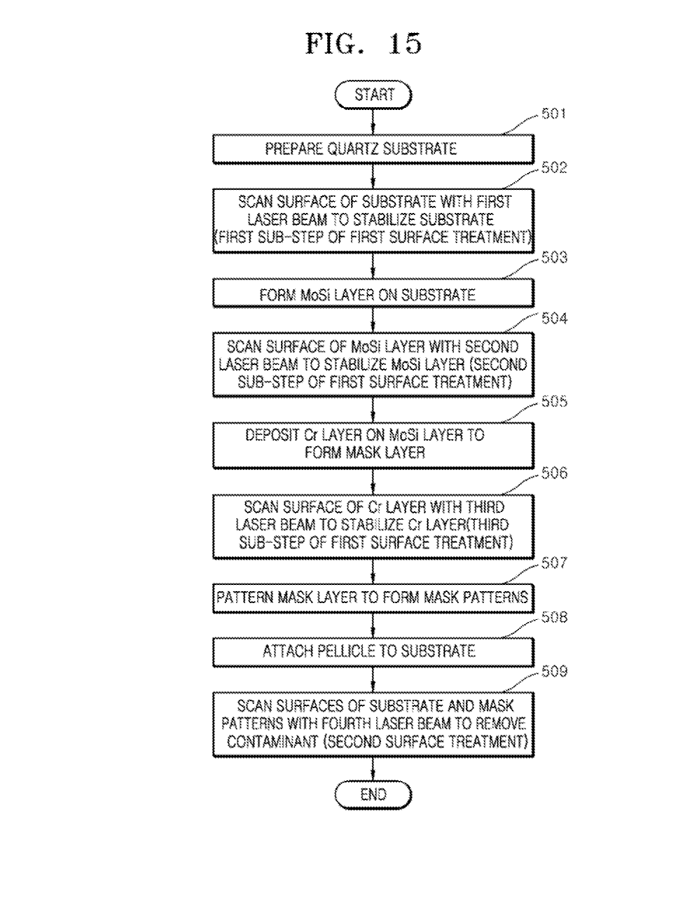

FIG. 15 is a process flowchart illustrating a method of cleaning a surface of a photomask according to another embodiment. Referring to FIG. 15, the surface cleaning method may include preparing a light transmitting substrate such as a quartz substrate (see a step 501), performing a first sub-step of a first surface treatment process for scanning a surface of the substrate with a first laser beam to stabilize the substrate (see a step 502), forming a first mask layer for example, a molybdenum silicon (MoSi) alloy layer on the substrate (see a step 503), performing a second sub-step of the first surface treatment process for scanning a surface of the first mask layer with a second laser beam to stabilize the first mask layer (see a step 504), forming a second mask layer for example, a chrome (Cr) layer on the first mask layer (see a step 505), and performing a third sub-step of the first surface treatment process for scanning a surface of the second mask layer with a third laser beam to stabilize the second mask layer (see a step 506). The first and second mask layers, in combination, may constitute a mask layer.

The first, second, and third sub-steps of the first surface treatment process may be independently performed. In some embodiments, one or two sub-steps among the first to third sub-steps of the first surface treatment process may be omitted. The first, second and third sub-steps of the first surface treatment process may be performed using the same process condition. For example, the first, second and third laser beams may have the same wavelength. The first surface treatment process 103 of the embodiment illustrated in FIG. 1 may correspond to the third sub-step of the first surface treatment process 506 illustrated in FIG. 15.

The surface cleaning method may further include patterning the mask layer to form mask patterns (see a step 507), attaching a pellicle to the substrate (see a step of 508), and performing a second surface treatment process for scanning surfaces of the mask patterns and the substrate with a fourth laser beam to remove contaminants (see a step 509).

The methods according to the aforementioned embodiments and structures formed thereby may be used in photolithography processes for fabricating integrated circuit (IC) chips. The IC chips may be supplied to users in a raw wafer form, in a bare die form or in a package form. The IC chips may also be supplied in a single package form or in a multi-chip package form. The IC chips may be integrated in intermediate products such as mother boards or end products to constitute signal processing devices. The end products may include toys, low end application products, or high end application products such as computers. For example, the end products may include display units, keyboards, or central processing units (CPUs).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A surface cleaning method comprising:
forming a mask layer over a substrate;
applying a first surface treatment to a surface of the mask layer using a first laser to stabilize the mask layer and the substrate;
forming a mask pattern by patterning the mask layer; and
applying a second surface treatment to surfaces of the mask pattern and the substrate using a second laser to remove contaminants over the mask pattern or the substrate.

2. The method of claim 1, wherein performing the second surface treatment includes:
applying thermal energy to the mask pattern and the substrate so that the thermal energy is transferred from the mask pattern and the substrate to the contaminants, and decomposes the contaminants.

3. The method of claim 2, wherein the second surface treatment is applied at least twice.

4. The method of claim 2, wherein the second laser beam has a wavelength which is within the range corresponding to a local maximum peak value of an absorption spectrum of the substrate or the mask pattern.

5. The method of claim 2, wherein the first laser has substantially the same wavelength band as the second laser beam.

6. The method of claim 2, wherein the first surface treatment is applied by repeatedly scanning the mask layer using the first laser,
wherein the first surface treatment is repeatedly applied at least twice,
wherein the substrate, the mask layer, or both are heated to a first temperature during the first surface treatment,
wherein the substrate, the mask pattern, or both are heated to a second temperature during the second surface treatment, and
wherein the first temperature is substantially the same as the second temperature.

7. The method of claim 6, wherein the first surface treatment is repeatedly applied at least twenty times.

8. The method of claim 6, further comprising:
repeatedly applying the second surface treatment to a test stack, wherein the test stack includes a test substrate and a test mask pattern;
calculating how many times the second surface treatment should be repeated to maintain a variation of the test mask pattern in size and property at or below a given value; and
calculating how many times the first surface treatment should be repeated based on the calculated repetition number of the second surface treatment.

9. The method of claim 1, further comprising:
attaching a pellicle to the substrate for protecting the mask pattern,
wherein the second laser beam penetrates the pellicle to reach the substrate and the mask pattern during the second surface treatment.

10. The method of claim 1,
wherein the mask layer includes a molybdenum silicon (MoSi) alloy layer, and
wherein the first laser scans a surface of the molybdenum silicon (MoSi) alloy layer.

11. The method of claim 1,
wherein the mask layer includes a molybdenum silicon (MoSi) alloy layer and a chrome (Cr) layer, and
wherein the first laser scans a surface of the chrome (Cr) layer.

12. A surface cleaning method comprising:
forming a first mask layer over a substrate;
forming a second mask layer over the first mask layer;
applying a first surface treatment to a surface of the substrate, a surface of the first mask layer, or a surface of the second mask layer using a first laser to stabilize the substrate, the first mask layer, or the second mask layer;
patterning the first and the second mask layers to form a mask pattern; and
applying a second surface treatment to surfaces of the mask pattern or the substrate using a second laser to remove contaminants over the mask pattern or the substrate.
